(19) United States
(12) Patent Application Publication
(10) Pub. No.: US 2014/0002069 A1
(43) Pub. Date: Jan. 2, 2014

(54) EDDY CURRENT PROBE

(71) Applicant: Kenneth Stoddard, Taylorsville, UT (US)

(72) Inventor: Kenneth Stoddard, Taylorsville, UT (US)

(21) Appl. No.: 13/534,807

(22) Filed: Jun. 27, 2012

(51) Int. Cl. G01R 33/12

(52) U.S. Cl. 324/239

(57) ABSTRACT

One example embodiment includes an eddy current probe. The eddy current probe includes an oscillator configured to produce a repetitive electronic signal. The eddy current probe also includes a sensing coil configured to receive the repetitive electronic signal from the oscillator and detect magnetic fields created by the repetitive electronic signal in a target and produce an electronic signal. The eddy current probe further includes a signal conditioner configured to produce an output signal based on the repetitive electronic signal and the electronic signal produced in the sensing coil.

### CROSS-REFERENCE TO RELATED APPLICATIONS

Not applicable.

### BACKGROUND OF THE INVENTION

Coils used as eddy current sensors detect a distance to a metallic target. The coils produce a nonlinear, logarithmic type response, which is in essence the displacement between the target and sense coil versus the coil's inductance. However, these coils are inherently sensitive to temperature. Electronic hardware with or without microprocessor/microcontroller assistance can linearize the response to sub percentage levels which somewhat compensates for the coil's thermal sensitivity. For example, microcode can perform calculations or make use of lookup tables to perform the linearization. These types of sensors have acceptable resolution for many applications, but not all of them.

Circuitry used by some manufacturer's monitor voltage levels as the displacement changes. To do that, either a frequency is generated that drives the coil in a bridge type manner or the coil is part of an oscillator's resonance circuit where the frequency is heavily filtered to obtain the displacement related voltage amplitude.

Frequency can also be used to directly transfer displacement information to an output. This may be accomplished with frequency counter type function; however, the bandwidth is lower compared to the other techniques. This is useful in situation in which speed is not a critical parameter.

Nevertheless, the highest resolution eddy sensing probes suffer with both large nonlinearities and high thermal sensitivities. These technologies normally use phase shift detection—at a set frequency—versus the more common but lower resolution amplitude detection methods. Therefore, with currently available eddy sensor probes, there is a tradeoff between the highest resolution and linear/thermal stability. Linearity is perhaps the lesser of the two parameters limiting the resolution; so, eddy current sensing resolution has been limited due to linearity, but mostly to temperature effects.

Phase shift detection generates time changes that correspond to phase. To accomplish phase shift detection, the coil is moved from its minimally thermal sensitive operating point with regard to the coil resistance. Each phase is at a different place from this minimum operating point, complicating this further.

Accordingly, there is a need in the art for an eddy current probe that produces frequency shifts that correspond to a metallic target movement from the sensing coil. Further, there is a need in the art for the eddy current probe to reduce thermal drift by minimizing coil resistance. Additionally, there is a need in the art for the output frequency from the oscillator to be processed by signal conditioning circuitry to linearize its overall response. Moreover, there is a need in the art for an eddy current probe which provides improved linearity, thermal stability, and bandwidth (frequency response or speed) for high resolution probes.

### BRIEF SUMMARY OF SOME EXAMPLE EMBODIMENTS

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter.

One example embodiment includes an eddy current probe. The eddy current probe includes an oscillator configured to produce a repetitive electronic signal. The eddy current probe also includes a sensing coil configured to receive the repetitive electronic signal from the oscillator and detect magnetic fields created by the repetitive electronic signal in a target and produce an electronic signal. The eddy current probe further includes a signal conditioner configured to produce an output signal based on the repetitive electronic signal and the electronic signal produced in the sensing coil.

Another example embodiment includes an eddy current probe. The eddy current probe includes an oscillator configured to produce a square wave. The oscillator includes a driver configured to provide a stable current. The oscillator includes a series resonator configured to receive the current from the driver and produce a sine wave at a desired frequency. The oscillator also includes an amplifier configured to amplify the sine wave produced by the series resonator and provide low impedance to the series resonator. The oscillator further includes a digital gate configured to convert the sine wave to a square wave. The oscillator additionally includes a first edge aligner configured to align the rising edge of the square wave to the voltage center of the rising edge of the sine wave. The oscillator moreover includes a second edge aligner configured to align the falling edge of the square wave to the voltage center of the falling edge of the sine wave. The eddy current probe also includes a sensing coil configured to receive the square wave from the oscillator and detect magnetic fields created by the square wave in a target and produce an electronic signal. The eddy current probe further includes a signal conditioner configured to produce an output signal based on the square wave and the electronic signal produced in the sensing coil.

Another example embodiment includes an eddy current probe. The eddy current probe includes an oscillator configured to produce a square wave. The oscillator includes a driver configured to provide a stable current. The oscillator includes a series resonator configured to receive the current from the driver and produce a sine wave at a desired frequency. The oscillator also includes an amplifier configured to amplify the sine wave produced by the series resonator and provide low impedance to the series resonator. The oscillator further a DC stop configured to remove any DC and low frequency signals from the sine wave. The oscillator additionally includes a digital gate configured to convert the sine wave to a square wave. The oscillator moreover includes a first edge aligner configured to align the rising edge of the square wave to the voltage center of the rising edge of the sine wave. The oscillator also includes a second edge aligner configured to align the falling edge of the square wave to the voltage center of the falling edge of the sine wave. The eddy current probe also includes a sensing coil configured to receive the square wave from the oscillator and detect magnetic fields created by the square wave in a target and produce an electronic signal. The eddy current probe further includes a signal conditioner configured to produce an output signal based on the square wave and the electronic signal produced in the sensing coil. The signal conditioner includes a main timing controller configured to control the timing for the complete data sampling period. The signal conditioner also includes an input time-to-voltage converter configured to measure the time interval between an event in the square wave and a return event measured by the sensing coil. The signal conditioner further includes a logarithmic curve generator configured to generate a logarithmic curve from the output of the main timing controller. The signal conditioner additionally includes a comparator configured to compare the measured time interval to the logarithmic curve produced by the logarithmic curve generator. The signal conditioner moreover includes a time-to-voltage converter configured to convert the output of the comparator to a voltage. The signal conditioner also includes an output conditioning block configured to produce an output signal from the voltage output by the time-to-voltage converter.

These and other objects and features of the present invention will become more fully apparent from the following description and appended claims, or may be learned by the practice of the invention as set forth hereinafter.

### BRIEF DESCRIPTION OF THE DRAWINGS

To further clarify various aspects of some example embodiments of the present invention, a more particular description of the invention will be rendered by reference to specific embodiments thereof which are illustrated in the appended drawings. It is appreciated that these drawings depict only illustrated embodiments of the invention and are therefore not to be considered limiting of its scope. The invention will be described and explained with additional specificity and detail through the use of the accompanying drawings in which:

FIG. 1 illustrates an example of an eddy current probe;

FIG. 2 illustrates a block diagram of an example of an oscillator; and

FIG. 3 illustrates a block diagram of an example of a signal conditioner.

### DETAILED DESCRIPTION OF SOME EXAMPLE EMBODIMENTS

Reference will now be made to the figures wherein like structures will be provided with like reference designations. It is understood that the figures are diagrammatic and schematic representations of some embodiments of the invention, and are not limiting of the present invention, nor are they necessarily drawn to scale.

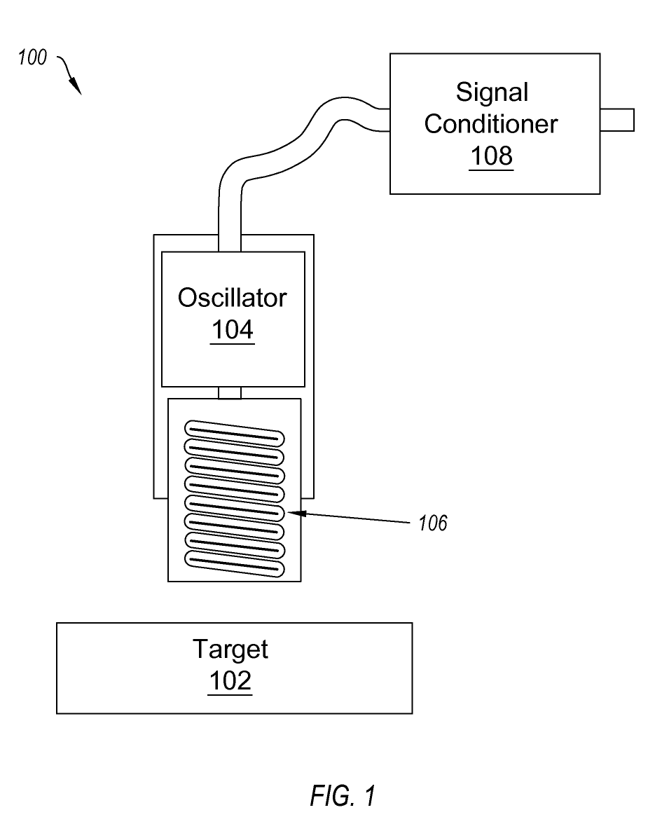

FIG. 1 illustrates an example of an eddy current probe 100. In at least one implementation, the eddy current probe 100 is a noncontact device capable of high-resolution measurement of the position and/or change of position of any conductive target. Such measurements can allow for detection of defects, damage or other potentially troublesome features in a conducting material. Additionally or alternatively, the measurements can allow for non-contact measuring of machine positioning. For example, if a machine or part is moving and contact will disrupt the motion or alignment of the machine, the eddy current probe 100 can be used to detect the position without contacting the machine or part.

FIG. 1 shows that the eddy current probe 100 can include a target 102. In at least one implementation, the target 102 can be any desired conductive material. A conductor is a material which contains movable electric charges. In metallic conductors such as copper or aluminum, the movable charged particles are electrons. However, a conductor in which the movable electrical charges are positive charges would also constitute an acceptable target 102

FIG. 1 also shows that the eddy current probe 100 can include an oscillator 104. In at least one implementation, the oscillator 104 is an electronic circuit that produces a repetitive electronic signal. For example, the oscillator can produce a sine wave or a square wave. One of skill in the art will appreciate that the better and more precise the creation of the repetitive electrical signal, the better the eddy current probe 100 will function, as described below.

FIG. 1 further shows that the eddy current probe 100 can include a sensing coil 106. In at least one implementation, the sensing coil is configured to detect a magnetic field. In particular, the repetitive electronic signal passes through the sensing coil 10b and is disrupted by the magnetic fields created in the target 102, as described below. For example, the sensing coil 106 can be formed when a conductor (e.g., an insulated solid copper wire) is wound around a core or form to create an inductor or electromagnet. One loop of wire is usually referred to as a turn, and a sensing coil 106 consists of one or more turns. For use in an electronic circuit, electrical connection terminals called taps are often connected to the sensing coil 106. A magnetic field induces a current in the sensing coil 106 which can be used to measure the strength of the magnetic field.

In particular, the electrical signal created by the oscillator 104 and passing through the sensing coil 106 will create eddy currents in the target 102 that creates, in turn, a magnetic field which can be measured by the sensing coil 106. Eddy currents (also called Foucault currents) are electric currents induced in conductors when a conductor is exposed to a changing magnetic field; due to relative motion of the field source and conductor or due to variations of the field with time. This can cause a circulating flow of electrons, or current, within the body of the conductor. These circulating eddies of current have inductance and thus induce magnetic fields. These fields can cause repulsive, attractive, propulsion and drag effects. The stronger the applied magnetic field, or the greater the electrical conductivity of the conductor, or the faster the field changes, then the greater the currents that are developed and the greater the fields produced.

FIG. 1 additionally shows that the eddy current probe 100 can include a signal conditioner 108. In at least one implementation, the signal conditioner 108 is configured to produce an output signal based on the signal created by the oscillator 104 and the magnetic field detected by the sensing coil 106. I.e., the signal conditioner 108 can compare the signal produced by the oscillator 104 and the signal received by the sensing coil 106 and produce an output signal. The output signal can be used to calculate the distance to the target 102 by the signal conditioner 108 or an external device.

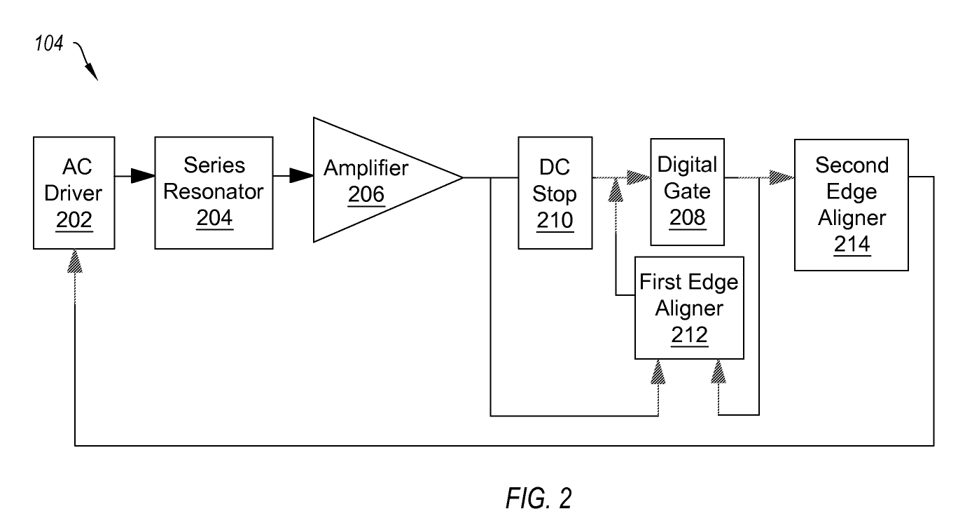

FIG. 2 illustrates a block diagram of an example of an oscillator 104. In at least one implementation, the oscillator 104 is configured to output a signal that is suitable for use in an eddy current probe. I.e., the oscillator 104 can produce a signal that is of suitable quality to produce a clean result in an eddy current probe. In particular, the oscillator 104 can produce a square-wave signal with minimal phase shift, as described below. The oscillator 104 can self-oscillate and can be capable of higher operating frequencies than typical eddy current probe oscillators which operate near 1 MHz. For example, the oscillator 104 can produce a square wave with a frequency greater than 2.5 MHz.

FIG. 2 shows that the oscillator 104 can include an AC driver 202. In at least one implementation, the AC driver 202 can include any device capable of providing a stable alternating current. I.e., the AC driver 202 provides a reliable source of electrical current that can be used by the oscillator to produce the desired oscillating signal. The impedance of the AC driver 202 can be kept low in order to prevent interference within the oscillator 104 minimizing phase shift within the oscillator 104.

FIG. 2 also shows that the oscillator 104 can include a series resonator 204. In at least one implementation, the series resonator 204 outputs an oscillating signal at a desired frequency when supplied with current from the AC driver 202. That is, the series resonator 204 has a natural frequency, which can be determined at its manufacture that affects the output signal. The result is a sine wave at the natural frequency of the series resonator 204. An adjustable and temperature sensitive capacitor can be configured to counterbalance the resonator inductance thermal sensitivity. Additionally or alternatively, the series resonator 204 can be configured to produce a minimal phase shift between it and the AC driver 202. The result is a lower thermally sensitive series resonator 204 due to resistance of the series resonator 204. Local feedback can be utilized to produce a consistent current level through the series resonator 204.

FIG. 2 further shows that the oscillator 104 can include an amplifier 206. In at least one implementation, the amplifier 206 is configured to amplify the sine wave created by the series resonator 204. I.e., the amplifier 206 can increase the voltage of the sine wave produced by the series resonator 204. The amplifier 206 can create low impedance for the series resonator 204. Low impedance ensures less interference from other circuitry for the series resonator 204. Additionally or alternatively, the amplifier 206 can generate a voltage from the current produced by the series resonator 204.

FIG. 2 additionally shows that the oscillator 104 can include a digital gate 208. In at least one implementation, the digital gate 208 can convert the sine wave to a square wave. I.e., the digital gate 208 can receive the sine wave and output a square wave. In particular, below a threshold value the output of the digital gate 208 is a “zero” or minimum voltage. Once the input voltage of the digital gate 208 exceeds the threshold value the digital gate 208 outputs a “1” or maximum voltage.

FIG. 2 moreover shows that the oscillator 104 can include a DC stop 210. In at least one implementation, the DC stop can prevent any DC signals from entering the digital gate 208. In particular, any noise introduced in the oscillator 104 manifests as a DC signal and low frequency. Therefore, the DC stop 210 removes DC and low frequency noise from the sine wave produced by the amplifier 206 and allows only the amplified sine wave to enter the digital gate 208.

FIG. 2 also shows that the oscillator 104 can include a first edge aligner 212. In at least one implementation, the first edge aligner 212 generates a DC voltage to drive the input of a digital gate 208. In particular, the first edge aligner 212 aligns the rising edge of the square wave with the voltage center of the rise edge of the amplified sine wave. Additionally or alternatively, the first edge aligner 212 thermally compensates for the input switching threshold of the digital gate 208. This allows the gate 208 to accurately convert the sine wave signal to a square wave.

FIG. 2 further shows that the oscillator 104 can include a second edge aligner 214. In at least one implementation, the second edge aligner 214 can create an approximately 50 percent duty cycle. That is, the second edge aligner 214 aligns the falling edge of the square wave to approximately the voltage center of the falling edge of the amplified sine wave, creating a square wave with an approximately 50 percent duty cycle. I.e., the first edge aligner 212 and the second edge aligner 214 can keep the sine wave and the square wave in phase with one another. As used in the specification and the claims, the term approximately shall mean that the value is within 10% of the stated value, unless otherwise specified.

FIG. 2 additionally shows that the square wave can be fed back to the AC driver 202. In at least one implementation, feeding back the square wave to the AC driver 202 can keep the drive signal in phase with its current thereby minimizing thermal sensitivity due to the resistance of the resonator 204.

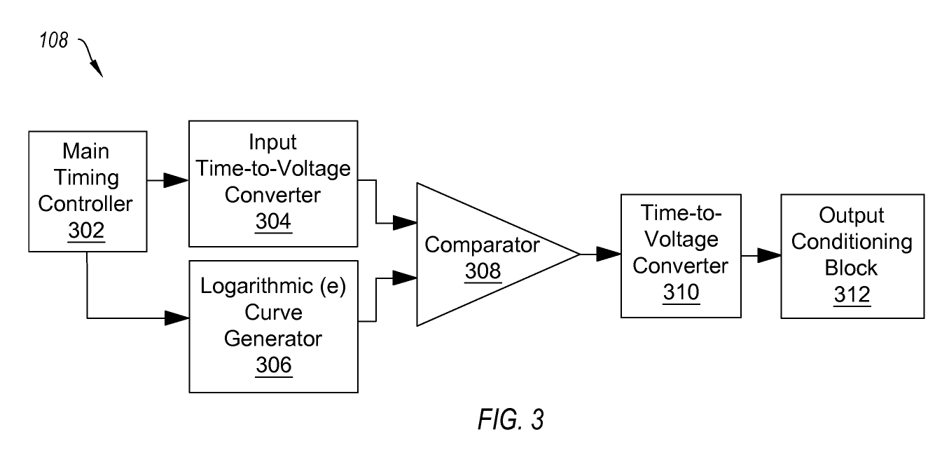

FIG. 3 illustrates a block diagram of an example of a signal conditioner 108. In at least one implementation, the signal conditioner 108 can produce a high resolution, linear voltage characteristic response from a resonator's frequency output, with a typical logarithmic characteristic response, in relationship to the displacement (or distance) between the resonator and a metallic target material.

FIG. 3 shows that the signal conditioner 108 can include a main timing controller 302. In at least one implementation, the main timing controller 302 controls timing for the complete data sampling period. That is, the timing controller 302 can establish a signal that acts as a baseline for the signal conditioner 108.

FIG. 3 also shows that the signal conditioner 108 can include an input time-to-voltage converter 304. In at least one implementation, the input time-to-voltage converter 304 can measure the time interval between two digital voltage pulses and store the result as a voltage. I.e., the input time-to-voltage converter 304 can create a voltage that is almost to the time of interest. For example, the input time-to-voltage converter 304 can establish the time between an output square wave and a return signal from a sensing coil. In particular, the majority of the resonator period (I/frequency) is removed prior to the ramp time. Only the amount of time corresponding to the minimum displacement through to the maximum displacement is used. Adjustments can be made to remove the remainder.

FIG. 3 further shows that the signal conditioner 108 can include a logarithmic curve generator 306. In at least one implementation, the logarithmic curve generator 306 can generate a logarithmic curve which can be used as a baseline to determine the distance between the oscillator and a target. In particular, the logarithmic curve generator 306 can act as a virtual target of a known distance from the oscillator, the distance to which can be compared to determine the actual distance of the target. One of skill in the art will appreciate that the main timing controller 302 can generate a logarithmic curve voltage. I.e., the logarithmic curve generator 306 can be integrated with the main timing controller 302.

FIG. 3 additionally shows that the signal conditioner 108 can include a comparator 308. In at least one implementation, the comparator 308 can compare the input voltage from the input time-to-voltage converter 302 and the logarithmic curve generator 306 with the difference output as a final signal. I.e., the output from the comparator 308 can be representative of the difference between the distance to the virtual target and the distance to the actual target. One of skill in the art will appreciate that the comparator 308 can obtain the result from multiple cycles, allowing for more accurate measurement and/or mapping of movement of the target. For example, the signal conditioner 108 can compares each cycle (or multiple cycles) against simple and adjustable logarithmic timers for accurate curve fitting. These adjustments can be controlled or accomplished by simple microprocessor code or analog hardware.

FIG. 3 moreover shows that the signal conditioner 108 can include a time-to-voltage converter 310. In at least one implementation, the time-to-voltage converter 310 generates a voltage level that corresponds to the linear time. I.e., the time-to-voltage converter 310 can be configured to convert the time output by the comparator 308 to a voltage which can be used to calculate the distance.

FIG. 3 also shows that the signal conditioner 108 can include an output conditioning block 312. In at least one implementation, the output conditioning block 312 can ensure that the output signal contains only the desired information. For example, the output conditioning block 312 can include a low-pass filter. A low-pass filter is an electronic filter that passes low-frequency signals but attenuates (reduces the amplitude of) signals with frequencies higher than the cutoff frequency. Additionally or alternatively, the output conditioning block 312 can include a gain circuit. In at least one implementation, the gain circuit can amplify the signal to a desired level. That is, the gain circuit can amplify the signal to a level where the output will be more useful. Additionally or alternatively, the output conditioning block 312 can include an offset adjustment circuit. A DC offset voltage at the inputs of an amplifier will contribute a significant error to the output. This is especially true in high gain configurations. An offset adjustment circuit can be added to “null” out the offset voltage, making high gain stages practical even with significant input offset voltages.

One of skill in the art will appreciate that using multiple oscillator cycles has an intrinsic gain benefit; each individual cycle multiplies the amplitude per sample time. This does increase the overall sample time—and lowers the bandwidth—with each additional cycle, but common eddy probe circuitry can filter the resonator frequency to remove the coil related frequency prior to linearization. That lowers their bandwidth and removes any potential gain advantage. A tradeoff of this benefit is gain versus noise stability, which is not uncommon with other types of gain.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. An eddy current probe, the eddy current probe comprising:
an oscillator configured to produce a repetitive electronic signal;
a sensing coil configured to:
receive the repetitive electronic signal from the oscillator; and
detect magnetic fields created by the repetitive electronic signal in a target and produce an electronic signal; and
a signal conditioner configured to produce an output signal based on the repetitive electronic signal and the electronic signal produced in the sensing coil.

2. The eddy current probe of claim 1, wherein the sensing coil includes:
a core; and
a conductor wrapped around the core.

3. The eddy current probe of claim 1, wherein the core is configured to produce a square wave.

4. The eddy current probe of claim 1, wherein the square wave includes a duty cycle of approximately 50 percent.

5. The eddy current probe of claim 1, wherein the oscillator includes a driver.

6. The eddy current probe of claim 1, wherein the oscillator includes a series resonator.

7. The eddy current probe of claim 1, wherein the oscillator includes an amplifier.

8. The eddy current probe of claim 1, wherein the oscillator includes a digital gate.

9. The eddy current probe of claim 1, wherein the oscillator includes a first edge aligner.

10. The eddy current probe of claim 9, wherein the oscillator includes a second edge aligner.

11. A eddy current probe, the eddy current probe comprising:
an oscillator:
configured to produce a square wave; and
including:
a driver configured to provide a stable current;
a series resonator configured to receive the current from the driver and produce a sine wave at a desired frequency;
an amplifier configured:
to amplify the sine wave produced by the series resonator; and
provide low impedance to the series resonator;
a digital gate configured to convert the sine wave to a square wave;
a first edge aligner configured to align the rising edge of the square wave to the voltage center of the rising edge of the sine wave; and
a second edge aligner configured to align the falling edge of the square wave to the voltage center of the falling edge of the sine wave;
a sensing coil configured to:
receive the square wave from the oscillator; and
detect magnetic fields created by the square wave in a target and produce an electronic signal; and
a signal conditioner configured to produce an output signal based on the square wave and the electronic signal produced in the sensing coil.

12. The eddy current probe of claim 11, wherein the signal conditioner includes an input time-to-voltage converter.

13. The eddy current probe of claim 11, wherein the signal conditioner includes a logarithmic curve generator.

14. The eddy current probe of claim 11, wherein the signal conditioner includes a comparator.

15. The eddy current probe of claim 11, wherein the signal conditioner includes an output conditioning block.

16. A eddy current probe, the eddy current probe comprising:
an oscillator:
configured to produce a square wave; and
including:
a driver configured to provide a stable current;
a series resonator configured to receive the current from the driver and produce a sine wave at a desired frequency;
an amplifier configured:
to amplify the sine wave produced by the series resonator; and
provide low impedance to the series resonator;
a DC stop configured to remove any DC signals from the sine wave;
a digital gate configured to convert the sine wave to a square wave;
a first edge aligner configured to align the rising edge of the square wave to the voltage center of the rising edge of the sine wave; and
a second edge aligner configured to align the falling edge of the square wave to the voltage center of the falling edge of the sine wave; and
a sensing coil configured to:
receive the square wave from the oscillator; and
detect magnetic fields created by the square wave in a target and produce an electronic signal; and
a signal conditioner:
configured to produce an output signal based on the square wave and the electronic signal produced in the sensing coil; and
including:
a main timing controller configured to control the timing for the complete data sampling period;
an input time-to-voltage converter configured to measure the time interval between an event in the square wave and a return event measured by the sensing coil;
a logarithmic curve generator configured to generate a logarithmic curve from the output of the main timing controller;
a comparator configured to compare the measured time interval to the logarithmic curve produced by the logarithmic curve generator;
a time-to-voltage converter configured to convert the output of the comparator to a voltage; and
an output conditioning block configured to produce an output signal from the voltage output by the time-to-voltage converter.

17. The eddy current probe of claim 16, wherein the output conditioning block includes a low-pass filter.

18. The eddy current probe of claim 16, wherein the output conditioning block includes a gain circuit.

19. The eddy current probe of claim 16, wherein the output conditioning block includes an offset adjustment circuit.

20. The eddy current probe of claim 16, wherein the frequency of the square wave is greater than 2.5 MHz.
